(19) United States
(12) Patent Application Publication
(10) Pub. No.: US 2012/0075862 A1
(43) Pub. Date: Mar. 29, 2012

(54) Decorative Lighting System

(76) Inventor: Raymundo Garcia, San Antonio, TX (US)

(21) Appl. No.: 12/893,858

(22) Filed: Sep. 29, 2010

(51) Int. Cl. F21S 4/00; H05K 13/00

(52) U.S. Cl. 362/249.16; 29/592.1

(57) ABSTRACT

A decorative lighting system comprising a plug adapted for electrical connection to a socket, and at least one light assembly electrically connected to the plug. Each light assembly comprises an at least partially-transparent housing having an interior and a light emitting device located within the interior and electrically connected to the plug. The housing comprises an irregularly-shaped sidewall to create a unique lighting effect. According to the preferred embodiment, the at least partially-transparent housing is a bottle. A body portion of the bottle is collapsed to approximately fifty percent of its original height, which causes irregular ridges to form in the external surface of the body portion. The collapsed shape of the bottle causes irregular redirection of light causing the emitted light to vary depending on the angle from which the assembly is viewed.

### CROSS-REFERENCES TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

The present invention is a lighting system. More specifically, the present invention is a decorative lighting system that combines traditional “Christmas-style” light strings with an at least partially-transparent housing comprising an irregularly-shaped sidewall.

### BRIEF SUMMARY OF THE INVENTION

The present invention is a decorative lighting system that provides a more brilliant and reflective light when compared to a “traditional” Christmas-style electric light strands. The invention comprises a plug adapted for electrical connection to a socket, and at least one light assembly electrically connected to the plug. Each light assembly comprises an at least partially-transparent housing having an interior and a light emitting device located within said interior and electrically connected to the plug. The housing comprises an irregularly-shaped sidewall to create a unique lighting effect. According to the preferred embodiment, the housing is constructed by deforming a plastic bottle. A body portion of the bottle is collapsed to approximately fifty percent of its original height, which causes irregularly-shaped and -spaced ridges to form in the sidewall of the body portion. The collapsed shape of the bottle causes irregular redirection of light causing the emitted light to vary depending on the angle from which the assembly is viewed.

### BRIEF DESCRIPTION OF THE SEVERAL VIEWS OF THE DRAWINGS

FIG. 1 is a side elevation of the preferred embodiment of the present invention.

FIG. 2 is an enlarged view of one of the bulbs of FIG. 1.

FIG. 3 is an alternative embodiment of a light assembly for use in the present invention.

### DETAILED DESCRIPTION OF THE INVENTION

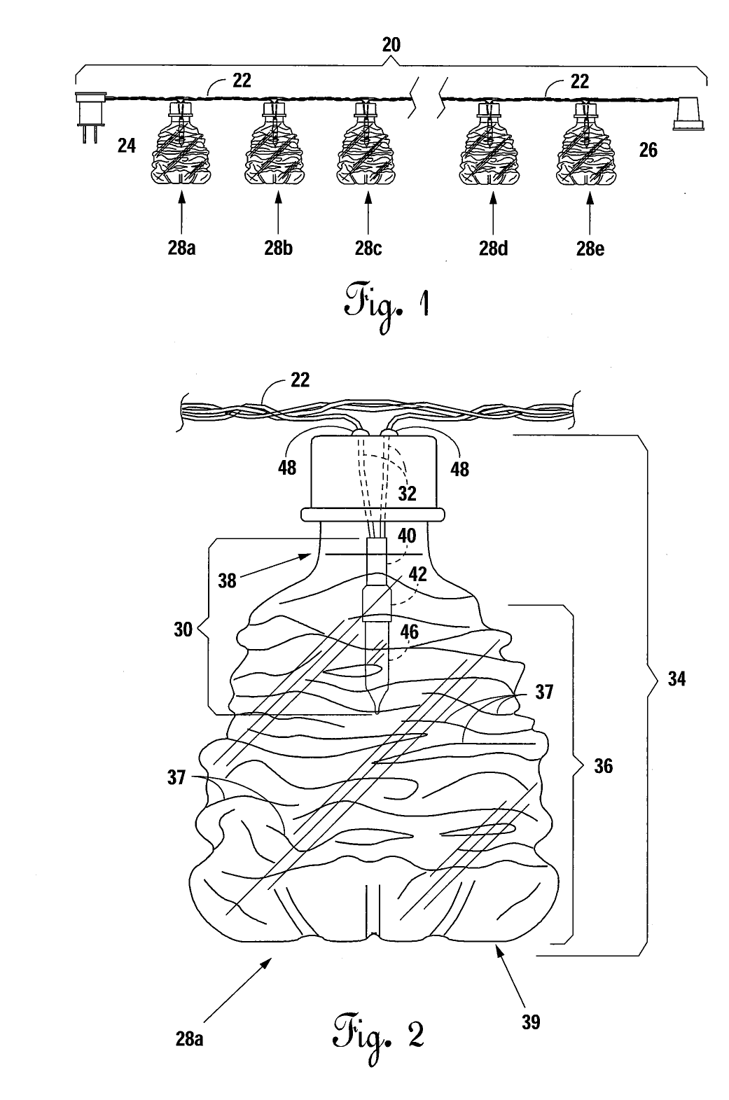

FIG. 1 is a side elevation of a preferred embodiment 20 of the present invention. The embodiment 20 includes a length of wires 22 electrically connecting a plug 24 to a socket 26. A number of identically-constructed lighting assemblies 28a-28e are approximately-equally spaced along the length 22. While FIG. 1 shows five specific assemblies 28a-28e, any number of such assemblies may be positioned electrically between the plug 24 and socket 26 depending on the electrical capacity and requirements of the wires and assemblies.

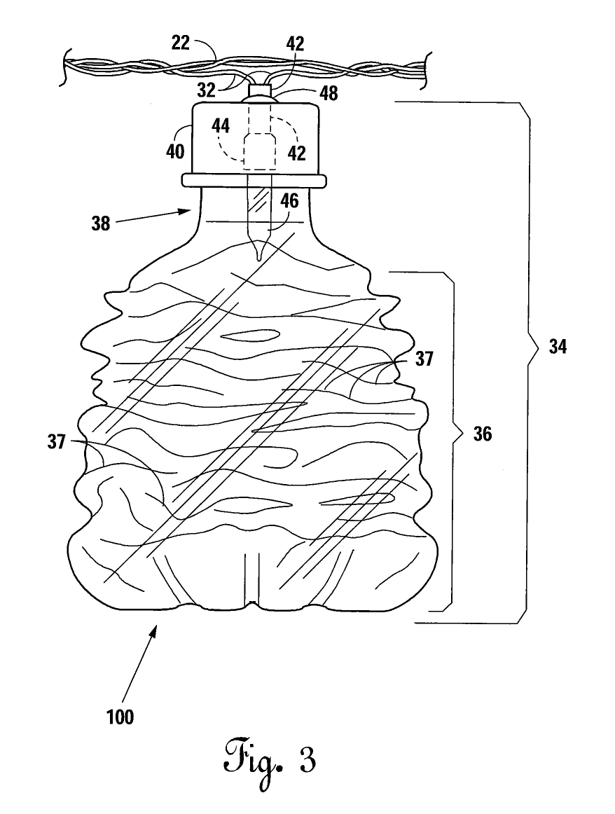

FIG. 2 shows one assembly 28a of FIG. 1 in greater detail. The assembly 28a includes a light emitting device 30 electrically connected to the length of wires 22 with leads 32, and a transparent plastic bottle 34 having a body portion 36, a neck portion 38 adjacent to the body portion 36, and a cap 40 threadable to the neck portion 38. The light emitting device 30 includes a generally-cylindrical base portion 42, a socket portion 44, and a bulb 46 electrically connected to the socket portion 44. Socket portion 44 is electrically connected to the length of wires 22 through leads 32. In this embodiment, the light emitting device 30 is an incandescent mini-light commonly found in strings of electric lights, but alternative embodiments contemplate the use of an LED assembly or any other type of decorative light emitter.

The light emitting device 30 is positioned within the body portion 36. Leads 32 run through the cap 40, and are adhered to the cap using a heat resistant adhesive 48 to hold the leads 32 in place and seal the interior of the bottle 36 to prevent ingress or egress of air or other fluids. Sealing in this manner helps maintain the deformed shape of the bottle 36 over time.

The bottle 36 has been deformed by partially crushing the body portion 36 into an irregular shape that is still generally cylindrical. This irregular shaping causes the surface of the body portion 36 to form irregularly-shaped and -spaced ridges 37 that act as light refracting surfaces. The irregular shaping causes the body portion 36 to direct light generated by the light emitting device 30 in irregular directions. Moreover, due to the irregular shaping, light that has traversed through the sidewall of the body portion 36 may then reenter the interior of the body portion 36. The deformed body portion 36 is approximately half its original height. Although FIG. 2 shows only one light emitting device 30 placed within the interior space of the bottle 34, a greater number of light emitting devices may be used.

The embodiment described with reference to FIGS. 1-2 may be made as follows. After the requisite materials are gathered, the caps 40 are removed from the neck portions 38 as necessary. Holes are drilled in the caps 40 to allow the leads 32 to pass from the light emitting device 30 to the length of wires 22. The length of wires 22 are cut at locations proximal to the light emitting devices 30, but sufficiently distal from the light emitting devices 30 to allow easy reconnection of the leads 32 to the length of wires 22. The leads 32 are then connected through the holes and reconnected to the length of wires 22. The leads 32 are thereafter secured in place using an adhesive, which is preferably heat resistant.

A generally cylindrical object, such as section of PVC tubing, is positioned through the neck of a bottle into the body portion 36 to contact and hold the bottom 39 of the bottle against a surface, such as flooring. Force is thereafter applied to the neck portion 38 in the direction of the surface to deform the body portion 36 to approximately half its original height. By using the generally-cylindrical object in this manner, the bottle retains a generally cylindrical shape during deformation process.

After deformation, the object is removed from the interior. The light emitting device 30, which is already wired to the cap 40, is then placed into the interior space of the body portion 36. The neck portion 38 is thereafter threaded to the cap 40.

FIG. 3 shows an alternative embodiment 100 of an assembly that may be used in the present invention. The cylindrical base portion 42 protrudes through the cap 40 and is adhered thereto with an adhesive 48. In this embodiment 100, the socket portion 44 of the light emitting device 30 is larger than the base portion 42.

In alternative embodiments, (a) the bottles 34 can be decorated and the caps 40 may be decorated so that the actual cap is hidden; (b) the exterior of the body portions 36 may be painted to alter the color of the filter of the emitted light.

The present invention is described above in terms of specifically-described embodiments of the invention. Those skilled in the art will recognize that alternative constructions can be used in carrying out the present invention. Other aspects, features, and advantages of the present invention may be obtained from a study of this disclosure and the drawings, along with the appended claims.

I claim:

1. A decorative lighting system comprising:
a plug adapted for electrical connection to a source of power;
a length of wires electrically connected to said plug;
at least one light assembly electrically connected to said length of wires, each light assembly comprising:
an at least partially-transparent housing having an interior and having an irregularly-shaped sidewall; and
a light emitting device located within said interior and electrically connected to said length of wires.

2. The decorative lighting system of claim 1 wherein said housing is a bottle.

3. The decorative lighting system of claim 1 wherein said bottle comprises a deformed body portion.

4. The decorative lighting system of claim 3 wherein said body portion is at least partially collapsed.

5. The decorative lighting system of claim 4 wherein said body portion has been collapsed to no more than sixty percent of its original height.

6. The decorative lighting system of claim 1 further comprising a socket electrically connected to said length of wires.

7. A method of making a decorative lighting system using at least one light emitting device electrically connected to a length of wires and at least one at least partially-transparent deformable bottle having a cap, a neck portion and a body portion, the method comprising the steps of:
inserting a generally-cylindrical object through the aperture of said at least one bottle;
apply a force with said object against the bottom of said body portion to immobilize said bottle against a surface;
apply a force to said bottle generally parallel to the longitudinal axis of said object, said force being sufficient to cause said body portion to collapse to a fraction of its original height;
engaging the bottle cap to the bottle.

8. The method of claim 7 further comprising the step of forming at least one hole in said caps of said at least one bottle.

9. The method of claim 8 further comprising the step of cutting the length of wires proximal to said at least one light emitting device to form leads connected to said light emitting device.

10. The method of claim 9 further comprising the step of running the leads through the at least one hole formed in caps.

11. The method of claim 10 further comprising the step of connecting the leads to the length of wires.

12. The method of claim 11 further comprising the step of securing the leads to the outside surface of the cap.
